(19) United States
(12) Patent Application Publication
(10) Pub. No.: US 2012/0119238 A1
(43) Pub. Date: May 17, 2012

(54) LED package structure

(75) Inventors: I Chih Huang, Shulin City (TW); Chun Yu Chai, New Taipei City (TW); Wen-Hsiung Li, Taichung City (TW)

(73) Assignee: Forward Electronics Co., Ltd., Taipei City (TW)

(21) Appl. No.: 13/064,001

(22) Filed: Mar. 2, 2011

(30) Foreign Application Priority Data
Nov. 17, 2010 (TW) 099222272

(51) Int. Cl. H01L 33/62

(52) U.S. Cl. 257/89; 257/E33.057

(57) ABSTRACT

An LED package structure includes an insulation substrate, a heat-sink slug, an LED chip assembly, four diodes, and a lead-frame assembly. The heat-sink slug is inserted on the insulation substrate, and includes a loading surface exposed externally, where the LED chip assembly is fixed on the loading surface. The lead-frame assembly includes two externally-extended lead frames and four loading lead frames which are apart from one another, and which are all inserted on the insulation substrate. The four diodes are correspondingly loaded on, and electrically connected with, the four loading lead frames. The LED chip assembly and the four diodes constitute a bridge circuit, wherein the bridge circuit has its positive electrode and negative electrode located at the two externally-extended lead frames, respectively. Therefore, there is no need for the LED package structure to connect externally a rectifier diode module so as to achieve the purpose of convenient use.

### BACKGROUND OF THE INVENTION

1. Field of the Invention

The present invention relates to a light emitting diode (LED) package structure, and more particularly, to an LED package structure adapted for use with an alternate current (AC) power supply.

2. Description of Related Art

When use of LEDs for illumination, because conventional LEDs require a lower voltage (about 3 volts), normally batteries are employed as a power supply. However, in case a public power supply is served directly, since an AC power supply has a voltage of 110 volts, the AC power supply needs to be rectified and regulated prior to serve as a power supply for conventional LEDs.

Currently high-voltage LED chips have been developed. Referring to FIG. 1, a perspective view illustrating a conventional high-voltage LED package structure, the high-voltage LED package structure 90 comprises an insulation substrate 901, a heat-sink slug 902, an LED chip assembly 903, a lead-frame assembly (including a positive-electrode lead frame 904a and a negative-electrode lead frame 904b ) and an encapsulation cover 905.

The heat-sink slug 902 and the lead frame assembly are both inserted on the insulation substrate 901. The LED chip assembly 903 refers to a single LED chip, or plural LED chips connected in parallel or in series, and disposed on the heat-sink slug 902, where the LED chip assembly 903, through wire bonding, is electrically connected to the positive-electrode lead frame 904a and the negative-electrode lead frame 904b. The encapsulation cover 905 encloses part of the insulation substrate 901 and the LED chip assembly 903.

To comply with a high-voltage input, a conventional high-voltage product needs to carry a rectifier diode module 91 externally of the high-voltage LED package structure 90. In other words, through two wires 92, the positive-electrode lead frame 904a and the negative-electrode lead frame 904b are electrically connected to the rectifier diode module 91 at two terminals 911,912, respectively, among four terminals 911 to 914. The other two terminals 913,914 of the rectifier diode module 91 are employed to be connected with an AC power supply.

The conventional high-voltage LED package structure 90 has a shortage, namely, a space for externally disposing the rectifier diode module 91 needs to be pre-arranged, and this is quite inconvenient for the use of conventional high-voltage LED products.

### SUMMARY OF THE INVENTION

An object of the present invention is to provide an LED package structure comprising an insulation substrate, a heat-sink slug, an LED chip assembly, four diodes, and a lead-frame assembly. The heat-sink slug is inserted on the insulation substrate, and includes a loading surface exposed externally, where the LED chip assembly is fixed on the loading surface.

The lead-frame assembly includes two externally-extended lead frames and four loading lead frames which are apart from one another, and which are all inserted on the insulation substrate. The four diodes are correspondingly loaded on, and electrically connected with, the four loading lead frames.

According to the present invention, the LED chip assembly and the four diodes constitute a bridge circuit, wherein the bridge circuit has its positive electrode and negative electrode located at the externally-extended lead frames, respectively.

Through the above package structure, according to the present invention, the shortage inherent in the conventional high-voltage LED package structure, where pre-arranging a space for externally disposing a rectifier diode module is necessary, can be solved. As such, a more convenient use for end users can be achieved.

According to the present invention, the LED chip assembly may include a plurality of LED chips connected in series with one another, or may be a single LED chip. The LED chip assembly may be of blue-light LED chip, yellow-light LED chip or red-light LED chip.

According to the present invention, the LED package structure may further comprise an encapsulation cover which encapsulates the LED chip assembly, where the encapsulation cover has a dome-like contour.

The heat-sink slug may be made of copper. The four diodes may be adhered and fixed to the corresponding loading lead frames by silicone.

Other objects, advantages, and novel features of the present invention will become more apparent from the following detailed description when taken in conjunction with the accompanying drawings.

### BRIEF DESCRIPTION OF THE DRAWINGS

FIG. 1 is a perspective view illustrating a conventional high-voltage LED package structure;

FIG. 2 is a perspective view illustrating an LED package structure, with part of an encapsulation cover removed, according to a first embodiment of the present invention;

FIG. 3 is a cross-sectional view illustrating the LED package structure according to the first embodiment of the present invention;

FIG. 4 is a schematic view illustrating a bridge circuit constituted by an LED chip assembly and four diodes according to the first embodiment of the present invention; and

FIG. 5 is a schematic view illustrating part of an LED package structure according to a second embodiment of the present invention.

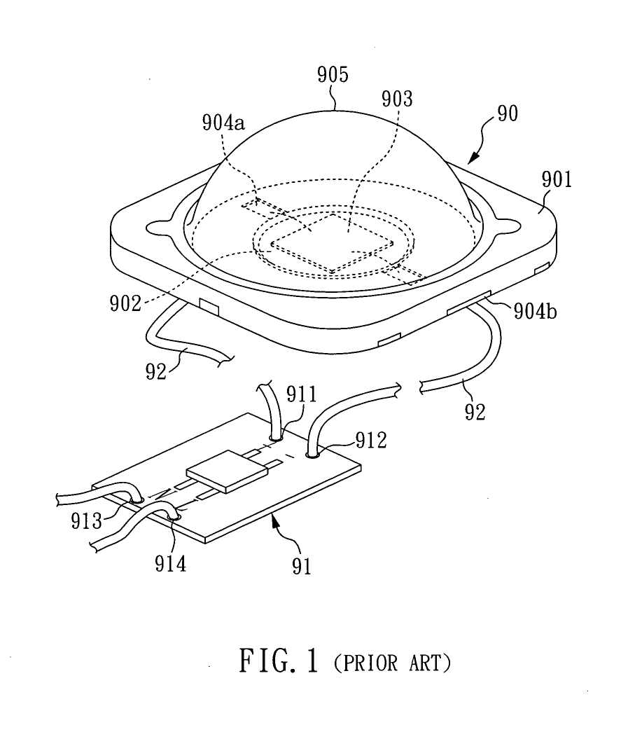

### DETAILED DESCRIPTION OF THE PREFERRED EMBODIMENTS

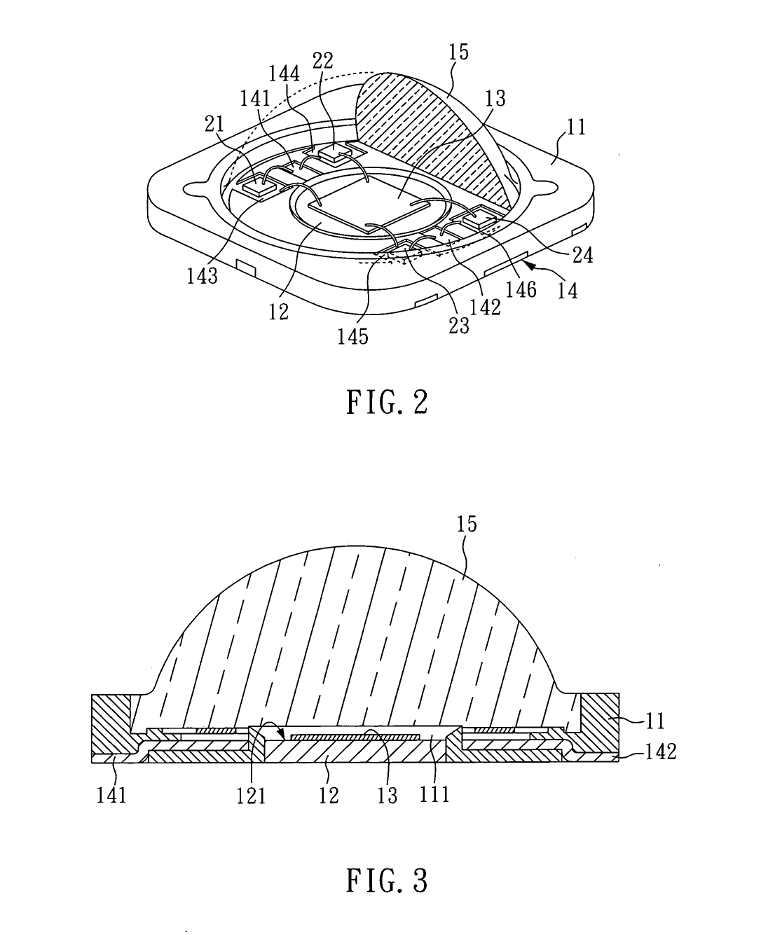

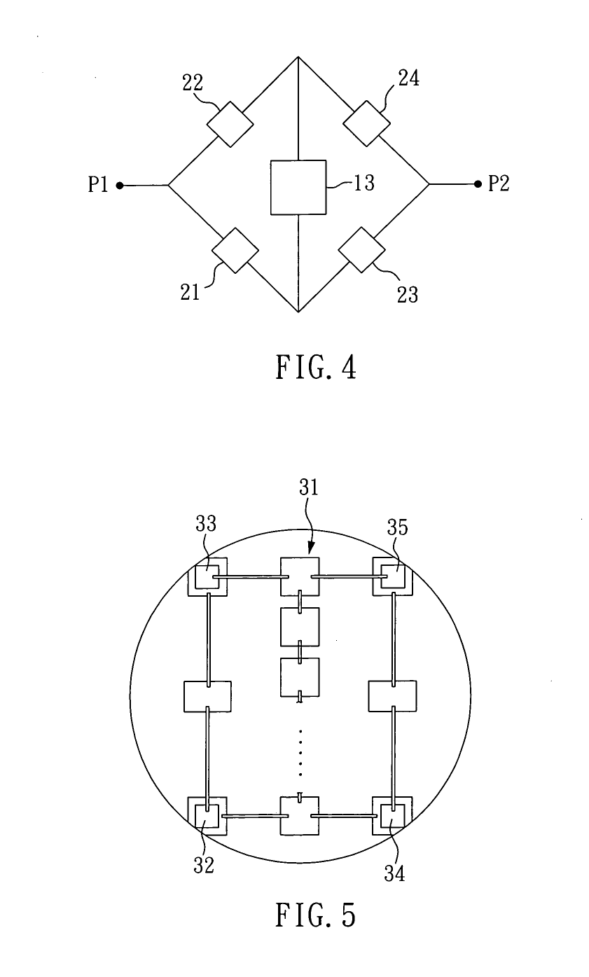

Referring to FIG. 2, a perspective view illustrating an LED package structure, with part of an encapsulation cover removed, according to a first embodiment of the present invention, to FIG. 3, a cross-sectional view illustrating the LED package structure, and to FIG. 4, a schematic view illustrating a bridge circuit constituted by an LED chip assembly and four diodes, the LED package structure comprises an insulation substrate 11, a heat-sink slug 12, an LED chip assembly 13, a lead-frame assembly 14, an encapsulation cover 15, and four diodes 21 to 24. The heat-sink slug 12 and the lead-frame assembly 14 are both inserted on the insulation substrate 11, where the insulation substrate 11 has a cup-like structure with a concave 111. The heat-sink slug 12 is, preferably, made of copper, with part of a surface portion (top surface) exposed from the insulation substrate 11 and toward the concave 111 (referred to as a “loading surface 121”), and part of the other surface portion (bottom surface) exposed from the insulation substrate 11.

The LED chip assembly 13 is loaded on the heat-sink slug 12. In the present embodiment, the LED chip assembly 13 relates to a single LED chip, such as a yellow-light LED chip, a blue-light LED chip, or a red-light LED chip.

The lead-frame assembly 14 includes two externally-extended lead frames 141,142 and four loading lead frames 143 to 146, where the six lead-frames 141 to 146 are apart from one another, and are all inserted on the insulation substrate 11, and are partially exposed to the concave 111. The two externally-extended lead frames 141,142 are of opposite polarity, acting as a positive- and a negative-electrode lead frames.

The four diodes 21 to 24 each has two opposite-polarity electrically connected terminals (P electrode and N electrode). In the present embodiment, the diode 21 is electrically connected, at the two electrically connected terminals, with the loading lead frame 143 and the externally-extended lead frame 141, respectively; the diode 22, at the two electrically connected terminals, with the loading lead frame 144 and the LED chip assembly 13; the diode 23, at the two electrically connected terminals, with the loading lead frame 145 and the externally-extended lead frame 142; and the diode 24, at the two electrically connected terminals, with the loading lead frame 146 and the LED chip assembly 13. The diodes 21 to 24 can be adhered and fixed to the corresponding loading lead frames 144 to 146 by silicone.

Further, through a wire bonding measure, the loading lead frame 143 can be electrically connected to the LED chip assembly 13, the loading lead frame 144 to the externally-extended lead frame 141, the loading lead frame 145 to the LED chip assembly 13, and the loading lead frame 146 to the externally-extended lead frame 142.

Through the above electrically-connected configuration, the LED chip assembly 13 and the four diodes 21 to 24 constitute a bridge circuit (see FIG. 4). The bridge circuit has its positive and negative electrodes located at the externally-extended lead frames 141,142, respectively.

The encapsulation cover 15 has a dome-like contour and encapsulates the concave 111 of the insulation substrate 11, the LED chip assembly 13, and the four diodes 21 to 24. Through a particular design on geometric shape, the light emitted from the chip can be more uniform and even more precise in direction. Of course, a fluorescent colloidal layer is interposed between the encapsulation cover 15 and the LED chip assembly 13, wherein the fluorescent colloidal layer is inside uniformilly spread with fluorescent particles for reaction with color-light emitted form the LED chip assembly 13. As commonly known, an LED chip with different color light needs to comply with different kinds of fluorescent particles.

Given the above, according to the present invention, it is understood that a spread lead frame design is employed so as to assemble together a bridge circuit consisting of four diodes and the LED chip assembly 13, where the bridge circuit is packaged in the same structure. As such, an LED product, which is driven directly by AC power supply, can be accomplished. Unlike the conventional art where consideration of pre-arranging a space for externally disposing a rectifier diode module is necessary, the present invention is comparatively not limited by space in the use of a high-voltage LED product.

Now referring to FIG. 5, a schematic view illustrating part of an LED package structure according to a second embodiment of the present invention, in the second embodiment an LED chip assembly 31 consists of a plurality of LED chips connected in series with one another. Such LED chip assembly 31, so constituted, can bear a high voltage. Likewise, the LED chip assembly 31 and four diodes 32 to 35 still need to constitute a configuration of bridge circuit.

Although the present invention has been explained in relation to its preferred embodiments, it is to be understood that many other possible modifications and variations can be made without departing from the scope of the invention as hereinafter claimed.

What is claimed is:

1. An LED package structure, comprising:
an insulation substrate;
a heat-sink slug, being inserted on the insulation substrate, and including a loading surface exposed externally;
an LED chip assembly, being fixed on the loading surface;
four diodes; and
a lead-frame assembly, including two externally-extended lead frames and four loading lead frames which are apart from one another, and which are all inserted on the insulation substrate, wherein the four diodes are correspondingly loaded on, and electrically connected with, the four loading lead frames, and wherein the LED chip assembly and the four diodes constitute a bridge circuit such that the bridge circuit has its positive electrode and negative electrode located at the two externally-extended lead frames, respectively.

2. The LED package structure as claimed in claim 1, wherein the LED chip assembly includes a plurality of LED chips connected in series with one another.

3. The LED package structure as claimed in claim 1, wherein the LED chip assembly includes a blue-light LED chip.

4. The LED package structure as claimed in claim 1, wherein the LED chip assembly includes a yellow-light LED chip.

5. The LED package structure as claimed in claim 1, wherein the LED chip assembly includes a red-light LED chip.

6. The LED package structure as claimed in claim 1, further comprising an encapsulation cover which encapsulates the LED chip assembly, wherein the encapsulation cover has a dome-like contour.

7. The LED package structure as claimed in claim 1, wherein the heat-sink slug is made of copper.

8. The LED package structure as claimed in claim 1, wherein the four diodes are adhered and fixed to the corresponding four loading lead frames by silicone.
